(19) United States
(12) Patent Application Publication
(10) Pub. No.: US 2017/0150638 A1
(43) Pub. Date: May 25, 2017

(54) COOLING APPARATUS FOR ENERGY CONVERTING UNITS

(71) Applicants: Youngbin Kim, Los Angeles, CA (US); Bokyoon Kim, Los Angeles, CA (US)

(72) Inventors: Youngbin Kim, Los Angeles, CA (US); Bokyoon Kim, Los Angeles, CA (US)

(21) Appl. No.: 14/948,233

(22) Filed: Nov. 20, 2015

(51) Int. Cl. H05K 7/20

(52) U.S. Cl. CPC H05K 7/20009

(57) ABSTRACT

The present invention pertains generally to a cooling apparatus using fluent material for energy converting units, such as photovoltaic cells, to harness solar energy. More particularly, the present invention pertains to water-based cooling apparatus, in a preferred embodiment, in which the apparatus is further configured to mount or mate with energy converting units that are mounted on solar panels that track movement of the sun during daylight hours.

### TECHNICAL FIELD

The present invention pertains generally to a cooling apparatus for energy converting units, such as photovoltaic cells, thermal-solar cells, concentrating cells, and the like, to harness solar energy.

### BACKGROUND OF THE INVENTION

The angle at which solar radiation is incident on an energy converting unit (e.g. a photovoltaic cell, thermal-solar cell, concentrating cell) can significantly affect the unit's ability to convert solar energy into electrical energy. In the present disclosure energy converting unit, solar cell module, photovoltaic cell, thermal-solar cell, and concentration cell will be used interchangeably. Optimally, the angle of incidence for solar radiation will be ninety degrees (i.e. an energy converting unit is oriented so solar radiation is directed at a right angle, perpendicular to the surface of the energy converting unit). To do this, specific tracking movements of the energy converting unit during daylight hours are required. This, however, may be difficult or impractical to achieve.

In order to effectively track movement of the sun, modern sun-tracking solar panels utilize both the azimuthal movements and elevation considerations for a solar panel. For example, the panel must first be pointed in the proper azimuthal direction (i.e. toward the sun). Secondly, with azimuth established, the panel must then be inclined in elevation to optimize (maximize) the angle of incidence. On the first point (i.e. azimuthal tracking), in comparison with a stationary solar panel it has been determined that the overall efficiency of energy converting units can be improved by approximately seventy percent when the solar panel azimuthally tracks the sun. On the second point, for latitudes of the United States, in comparison with a horizontally oriented solar panel, an inclination angle for elevation of a range between about ten to thirty degrees has been determined to be generally optimal.

Given the foregoing, many sun tracking solar panels provide a system for moving an energy converting unit that azimuthally tracks the sun with a fixed elevation angle, to thereby maximize solar energy utilization and provide a system for moving an energy converting unit in accordance with a programmed schedule of cycles which tracks the sun during daylight hours that recycles the system at nighttime in preparation for a subsequent cycle the next day. However, one of the main obstacles that face the operation of photovoltaic panels (PV), or energy converting units utilizing the sun, is overheating due to excessive solar radiation and high ambient temperatures—overheating reduces the efficiency of the panels dramatically.

Despite many advances in recent decades, solar cells suffer from efficiency problems. Only a small amount of the energy from sunlight that falls on solar cells is converted to electricity, peaking at below 20 percent for most cells on the market today. Overheating is a constant problem because the sunlight used to generate electricity routinely heats up the panels to 130° F. (55° C.) or higher. This heating causes a multitude of problems—not the least of which is a dramatic drop in efficiency.

There exists a need for a cooling apparatus which overcomes the above noted objections.

### SUMMARY OF THE INVENTION

The present disclosure addresses the above stated situation by providing a cooling apparatus for photovoltaic panels (PV), and the like, that are prone to overheating due to excessive solar radiation and high ambient temperatures.

It is an object to provide improved elements and arrangements thereof by apparatus for the purposes described which is inexpensive, dependable, and fully effective in accomplishing its intended purposes.

These and other objects will become readily apparent upon further review of the following specification and drawings.

### BRIEF DESCRIPTION OF THE DRAWINGS

The drawings, when considered in connection with the following description, are presented for the purpose of facilitating an understanding of the subject matter sought to be protected.

FIG. 1 is a side view showing the condensing type solar energy generating apparatus in which the invention is applied to.

FIG. 2 is a cross-sectional view showing the solar cell module of the condensing type solar energy generating apparatus in which the invention is applied to.

### DETAILED DESCRIPTION

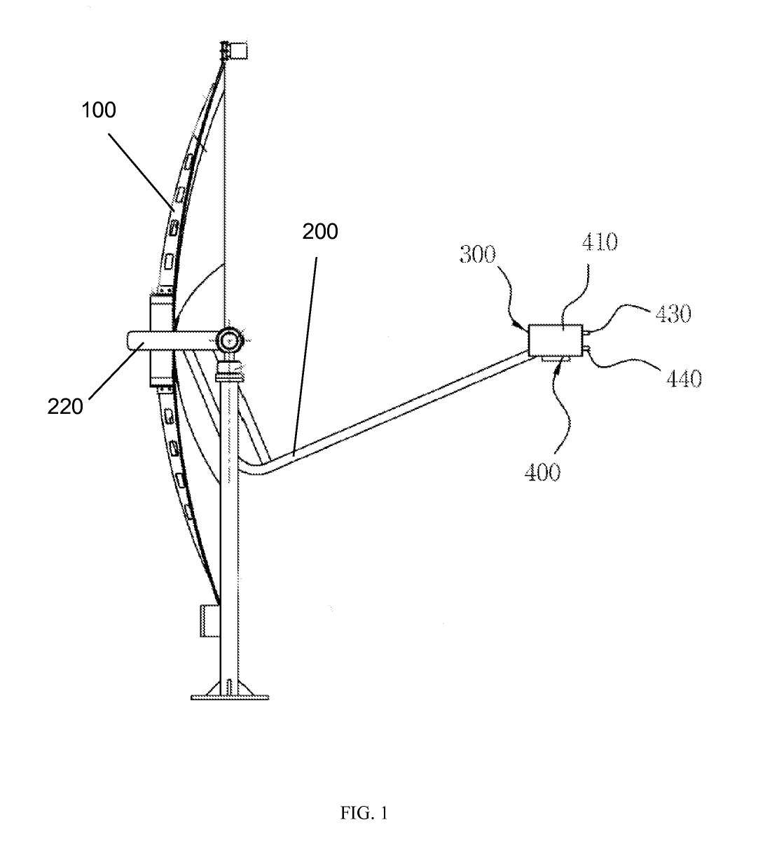

Referring now to the FIG. 1, according to at least one aspect of the invention, there is shown an apparatus in which energy converting units are mounted on solar panels that track movement of the sun during daylight 100. An apparatus in accordance with the present invention, a cooling module 400, is shown attached to an apparatus in which energy converting units are mounted on solar panels that track movement of the sun during daylight 100. The cooling module can affix itself to any sun-tracking solar module with the use of an attachment member 200, which may utilize any means known in the art to attach itself to, for example, an apparatus in which energy converting units are mounted on solar panels that track movement of the sun during daylight 100. The foregoing attachment member 200 is adaptable to mate with a locking member 220 that is selectively engageable to attach to a solar panel, a mount for supporting said solar panel, a means for rotating said solar panel, such as a motor or gear, a pole anchored to the ground supporting said mount, and disposed to attach to any component of said energy converting units that are mounted on solar panels that track movement of the sun during daylight 100, in an illustrative embodiment. For purposes of the present invention, the shape of the cooling module 400 is substantially rectangular, however, in alternate embodiments the cooling module 400 may utilize different housing shapes and sizes depending on the size and dimensions of the energy converting unit to which it is attached.

Moreover, the cooling module 400 includes a circulation housing 410 for storing a fluent material, such as water, too absorb the heat dissipated by the solar cell module 300. In this regard, there is also shown an inlet port 430 where a user can inject a fluent material, such as water, into the circulation housing 410. Heat absorbed by the cooling module 400 is further released by a vent 440. It is to be appreciated that the cooling module 400 may utilize one or more inlet ports 430 and one or more vents 440 depending on the embodiment and needs of the user.

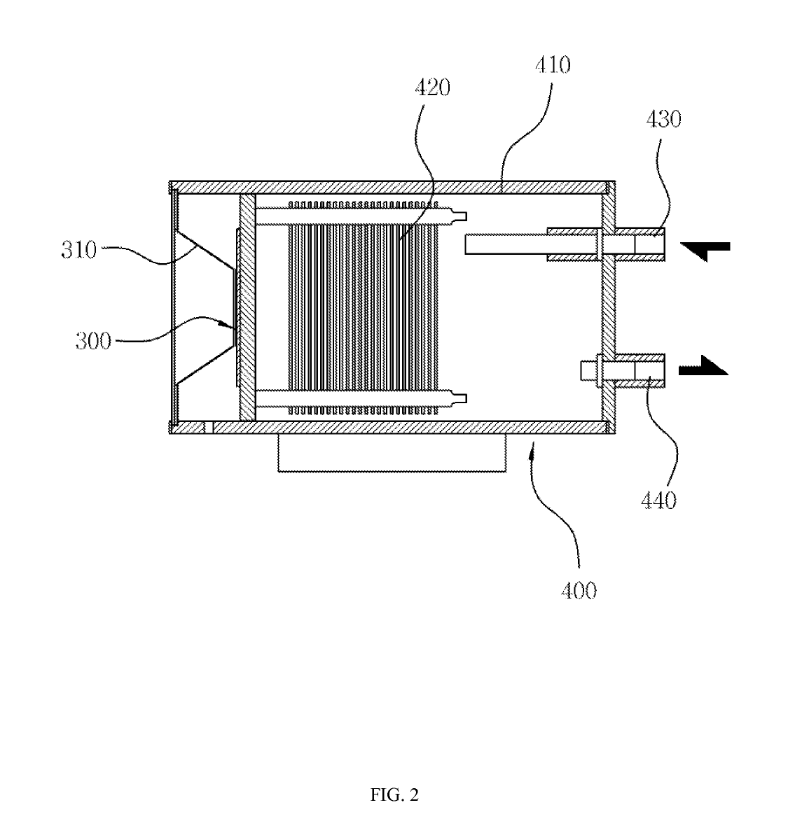

Additional structural aspects of the present invention will be best appreciated with reference to FIG. 2 where it can be seen that the cooling module 400 is fixably attacheable to the rear of the energy converting unit 300 and a plurality of light concentration guide plates 310. The circulation housing 410 uses fluent material, which may be recycled, whereby heat generated by the solar cell module 300 and light concentration guide plate 310 are absorbed and uniformly distributed to the fluent material in the circulation housing 410. It is to be understood that heat can escape said circulation housing 410 through the use of one or more air vents 440, wherein said circulation housing has the necessary means to circulate the fluent material so as to constantly dissipate and release heat through said vents 440. Moreover, the cooling module 400 is further adapted to maintain a core operating temperature range of 25-35 degrees Celsius with regards to the solar cell module 300. The cooling module is further comprised of a plurality of cooling pins 420, wherein said cooling pins are operative to release and absorb heat generated in said solar cell module 300 and transfer said heat to the fluent material of the circulation housing 410. As previously mentioned the one or more inlet ports 430 is configured to receive fluent material, by known means prevalent in the art, to supply said circulation housing 410 with such fluent material.

While the present disclosure has been described in connection with what is considered the most practical and preferred embodiment, it is understood that this disclosure is not limited to the disclosed embodiments, but is intended to cover various arrangements included within the spirit and scope of the broadest interpretation so as to encompass all such modifications and equivalent arrangements. Also, as used herein, including in the claims, the terms first, second, third, etc . . . used in relation to an element are for reference or identification purposes only, and these terms, unless otherwise indicated, are not intended to describe or suggest a number, order, source, purpose, or substantive quality for any element for which such a term is used.

1. An apparatus for cooling an energy converting unit for the production of electric and thermal energy, to maximize solar energy utilization which comprises:
a cooling module, wherein said cooling module is fixably attacheable to the rear of the energy converting unit and a plurality of light concentration guide plates, and further comprised of:
a circulation housing, wherein said circulation housing uses recycled fluent material whereby heat generated by the energy converting united is absorbed and uniformly distributed to the fluent material, wherein said heat can escape said circulation housing through the use of one or more air vents, wherein said circulation housing having the necessary means to maintain a normal operating temperature range of 25-35 degrees Celsius with regards to the energy converting unit;
a plurality of cooling pins, wherein said cooling pins are operative to release and absorb heat generated in said energy converting unit and transfer said heat to the fluent material of the circulation housing;
one or more inlet ports, wherein each of said inlet ports is further adapted to receive fluent material to supply said circulation. housing;
an attachment member, wherein said attachment member is adaptable to mate with a. locking member selectively engageable to attach to:
a solar panel, a mount for supporting said solar panel, a means for rotating said solar panel, a pole anchored to the ground supporting said mount, and disposed to attach to any component of said energy converting unit.

2. The apparatus of claim 1, wherein said cooling pins are fixably attachable within said circulation housing wherein the cooling module is removeably attachable to an energy converting unit.

3. The apparatus of claim 1, wherein said fluent material includes water at various temperatures.
